(19) United States
(12) Patent Application Publication
(10) Pub. No.: US 2024/0385535 A1
(43) Pub. Date: Nov. 21, 2024

(54) STRUCTURES FOR USE ON A SUBSTRATE HOLDER, SUBSTRATE HOLDER, LITHOGRAPHIC APPARATUS AND METHOD

(71) Applicant: ASML NETHERLANDS B.V., Veldhoven (NL)

(72) Inventors: Gijs KRAMER, Nijmegen (NL); Siegried Alexander TROMP, Knegsel (NL); Tjarco LINDEIJER, Heeze (NL); Adrianus Petrus Cornelis HELLEMONS, Waalre (NL); Bas Johannes Petrus ROSET, Eindhoven (NL)

(73) Assignee: ASML NETHERLANDS B.V., Veldhoven (NL)

(21) Appl. No.: 18/570,140

(22) PCT Filed: May 30, 2022
(86) PCT No.: PCT/EP2022/064570

§ 371 Date: Dec. 14, 2023

(30) Foreign Application Priority Data
Jun. 24, 2021 (EP) 21181588.1
Sep. 8, 2021 (EP) 21195600.8

(51) Int. Cl. G03F 7/00; H01L 21/687

(52) U.S. Cl. CPC G03F 7/707; H01L 21/6875

(57) ABSTRACT

A structure for use on a base surface of a substrate holder, wherein the structure is substantially planar with a substrate holder facing surface that is both securable to the base surface of the substrate holder and also removable from the base surface of the substrate holder, the structure having a plurality of apertures therethrough that are arranged such that a plurality of burls on the base surface may pass through the respective apertures, wherein the diameter of the apertures is in the range 50 μm to 1000 μm and the pitch between adjacent apertures is in the range 1 mm to 3 mm.

### CROSS-REFERENCE TO RELATED APPLICATIONS

This application claims priority of EP application Ser. No. 21/181,588.1 which was filed on 24 Jun. 2021, and EP application Ser. No. 21/195,600.8 which was filed on 8 Sep. 2021, which are incorporated herein in its entirety by reference.

### FIELD

The present invention relates to a substrate holder for supporting a substrate, a lithographic apparatus comprising the substrate holder, structures for securing to the substrate holder, a method of supporting a substrate on the substrate holder, and a method of clamping a substrate on the substrate holder.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as “Moore's law”. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

A lithographic apparatus may include an illumination system for providing a projection beam of radiation, and a support structure for supporting a patterning device. The patterning device may serve to impart the projection beam with a pattern in its cross-section. The apparatus may also include a projection system for projecting the patterned beam onto a target portion of a substrate.

In a lithographic apparatus the substrate to be exposed (which may be referred to as a production substrate) may be held on a substrate holder (sometimes referred to as a wafer table). The substrate holder may be moveable with respect to the projection system. The substrate holder usually comprises a solid body made of a rigid material and having similar dimensions in plan to the production substrate to be supported. The substrate-facing surface of the solid body may be provided with a plurality of projections (referred to as burls). The distal surfaces of the burls may conform to a flat plane and support the substrate. The burls can provide several advantages: a contaminant particle on the substrate holder or on the substrate is likely to fall between burls and therefore does not cause a deformation of the substrate; it is easier to machine the burls so their ends conform to a plane than to make the surface of the solid body flat; and the properties of the burls can be adjusted, e.g. to control clamping of the substrate to the substrate holder.

Production substrates may become distorted during the process of manufacturing devices, especially when structures with significant height, e.g. so-called 3D-NAND, are formed. Often substrates may become “bowl-shaped”, i.e. are concave viewed from above, or “umbrella-shaped”, i.e. convex viewed from above. For the purpose of the present disclosure the surface on which device structures are formed is referred to as the top surface. In this context, “height” is measured in the direction perpendicular to the nominal surface of the substrate, which direction may be referred to as the Z-direction. Bowl-shaped and umbrella-shaped substrates are, to a certain degree, flattened out when clamped onto a substrate holder, e.g. by partially evacuating the space between the substrate and substrate holder. However, if the amount of distortion, which is typically measured by the height difference between the lowest point on the surface of the substrate and the highest point on the surface of the substrate, is too great, various problems can arise. In particular, it may be difficult to clamp the substrate adequately, there may be excessive wear of the burls during loading and unloading of substrates and the residual height variation in the surface of the substrate may be too great to enable correct patterning on all parts of the substrate, especially close to the edges.

### SUMMARY

An object of the present invention is to provide a substrate holder that enables effective pattern formation on a substrate. A substrate holder according to an embodiment may advantageously be easily adapted to improve the clamping of a substrate.

According to a first aspect of the invention, there is provided a structure for use on a base surface of a substrate holder, wherein: the structure is substantially planar with a substrate holder facing surface that is both securable to the base surface of the substrate holder and also removable from the base surface of the substrate holder; and the structure comprises a plurality of apertures therethrough that are arranged such that a plurality burls on the base surface may pass through the respective apertures; wherein: the diameter of the apertures is in the range 50 μm to 1000 μm; and the pitch between adjacent apertures is in the range 1 mm to 3 mm.

According to a second aspect of the invention, there is provided a substrate holder configured to support a substrate, the substrate holder comprising: a base surface; a plurality of burls protruding from the base surface, wherein each burl has a distal end and the plurality of burls are arranged such that, when the substrate is supported by the substrate holder, the substrate is supported by the distal ends of the plurality of burls; and at least one structure according to the first aspect secured to the base surface.

According to a third aspect of the invention, there is provided a substrate holder and one or more structures according to the first aspect, wherein the substrate holder is configured to support a substrate, and the substrate holder comprises: a base surface; and a plurality of burls protruding from the base surface, wherein each burl has a distal end and the plurality of burls are arranged such that, when the substrate is supported by the substrate holder, the substrate is supported by the distal ends of the plurality of burls.

According to a fourth aspect of the invention, there is provided a lithographic apparatus comprising a substrate holder according to the second aspect; and/or a substrate holder and one or more structures according to the third aspect.

According to a fifth aspect of the invention, there is provided a method of adapting a substrate holder, the method comprising: obtaining a substrate holder that comprises a base surface; and securing one or more structures according to the first aspect to the base surface; wherein the substrate holder is configured to support a substrate and the substrate holder comprises a plurality of burls protruding from the base surface, wherein each burl has a distal end and the plurality of burls are arranged such that, when the substrate is supported by the substrate holder, the substrate is supported by the distal ends of the plurality of burls.

According to a sixth aspect of the invention, there is provided a substrate holder, comprising: a base surface; a plurality of burls that project from the base surface and are configured to support a substrate; and a plurality of removable structures on the base surface; wherein: the plurality of removable structures each have a different thicknesses; and the plurality of removable structures are each formed with a plurality of holes so as to accommodate a portion of the plurality of burls.

According to a seventh aspect of the invention, there is provided a substrate holder, comprising: a base surface; a plurality of burls that project from the base surface and are configured to support a substrate; and a plurality of removable structures on the base surface; wherein: the plurality of removable structures each have a different thicknesses; and the plurality of removable structures each comprise an adhesive layer for adhering the structure to the base surface.

According to an eighth aspect of the invention, there is provided a substrate holder, comprising: a base surface; a plurality of burls that project from the base surface and are configured to support a substrate; and a plurality of removable structures on the base surface; wherein: the plurality of removable structures each have a different thicknesses; and the plurality of removable members each comprise one or more of a thermoplastic material, polyether ether ketone, polyethylene and metal.

Further embodiments, features and advantages of the present invention, as well as the structure and operation of the various embodiments features and advantages of the present invention, as well as the structure and operation of the various embodiments of the present invention, are described in detail below with reference to the accompanying drawings.

### BRIEF DESCRIPTION OF THE DRAWINGS

Embodiments of the invention will now be described by way of example only, with reference to the accompanying schematic drawings in which corresponding reference symbols indicate corresponding parts, and in which:

FIG. 1 schematically depicts an overview of a lithographic apparatus;

FIG. 2 depicts a cross section of part of a known substrate holder;

FIG. 3 depicts a plan view of the substrate holder of FIG. 2;

FIG. 4 depicts structures on a substrate holder according to an embodiment;

FIG. 5 depicts structures on a substrate holder according to an embodiment; and

FIG. 6 is a flowchart of a method according to an embodiment.

The features shown in the figures are not necessarily to scale, and the size and/or arrangement depicted is not limiting. It will be understood that the figures include optional features which may not be essential to the invention. Furthermore, not all of the features of the substrate holder are depicted in each of the figures, and the figures may only show some of the components relevant for a describing a particular feature.

### DETAILED DESCRIPTION

In the present document, the terms “radiation” and “beam” are used to encompass all types of electromagnetic radiation, including ultraviolet radiation (e.g. with a wavelength of 436, 405, 365, 248, 193, 157, 126 or 13.5 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

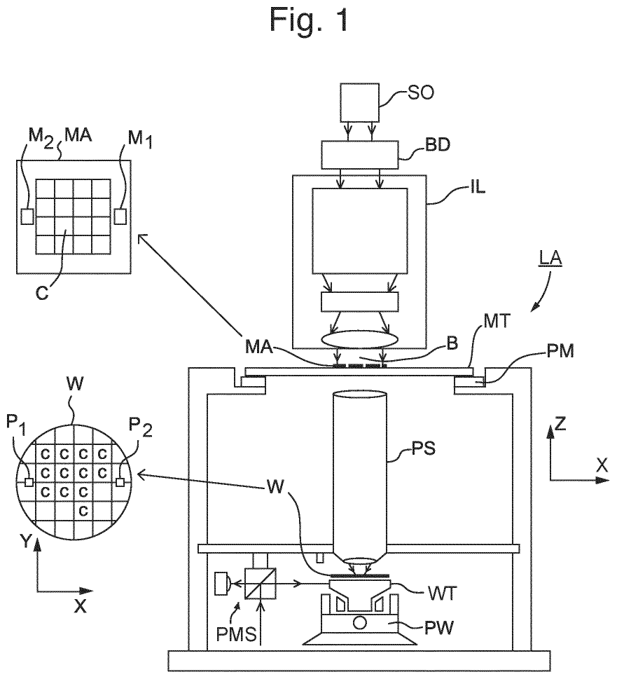

FIG. 1 schematically depicts a lithographic apparatus LA. The lithographic apparatus includes an illumination system (also referred to as illuminator) IL configured to condition a radiation beam B (e.g., EUV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus may be of a type wherein at least a portion of the substrate W may be covered by an immersion liquid having a relatively high refractive index, e.g., water, so as to fill an immersion space between the projection system PS and the substrate W-which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in FIG. 1). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system PMS, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

In this specification, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

In a lithographic apparatus it is necessary to position with great accuracy the upper surface of a substrate to be exposed in the plane of best focus of the aerial image of the pattern projected by the projection system. To achieve this, the substrate can be held on a substrate holder. The surface of the substrate holder that supports the substrate can be provided with a plurality of burls whose distal ends can be coplanar in a nominal support plane. The burls, though numerous, may be small in cross-sectional area parallel to the support plane so that the total cross-sectional area of their distal ends is a few percent, e.g. less than 5%, of the surface area of the substrate. The gas pressure in the space between the substrate holder and the substrate may be reduced relative to the pressure above the substrate to create a force clamping the substrate to the substrate holder.

It may be desirable to alter the applied forces for clamping a substrate to a surface of the substrate holder. This will be described in relation to a substrate holder which can be used to keep a substrate in a predetermined position, for example, during exposure of the substrate to radiation (i.e. when being patterned as described above).

As mentioned, it is desirable to increase the height of structures formed on a substrate. It has generally been found that distortion of a substrate positioned on a substrate holder tends to increase as the height of these structures increases, making reliable clamping of the substrate on the substrate holder more difficult.

The clamping can be made more reliable even taking the increased height into account. A first option is to increase the flow rate of fluid extracted beneath the substrate when the substrate is positioned on the substrate holder. A second option is the reduce the gap between the substrate and the substrate holder when in position on the substrate holder, i.e. by making the burls shorter. Both these options may improve the clamping when the substrate is in position on the substrate holder. However, both these options may have detrimental effects.

When a substrate is loaded onto a substrate holder, the substrate does not necessarily land perfectly flat on the substrate holder. This means that during loading of a substrate, one point of the substrate tends to make contact with at least one of the burls and then the rest of the substrate comes into contact with the substrate holder. Frictional forces between the substrate and the substrate holder during loading may lead to in-plane deformation in the substrate as the substrate makes contact across the substrate holder. The in-plane deformation can increase overlay errors. Both options described above for improving clamping may lead to increased in-plane deformation in the substrate, leading to greater overlay error.

Thus, although these options may improve clamping of the substrate, they can also lead to increased overlay errors which reduces throughput. The flow can be reduced for clamping the substrate to ameliorate the negative impact, but this increases the amount of time taken to clamp the substrate and thus, also decreases throughput. Additionally, the flow rate may affect substrates differently depending on how flat the substrate is during loading. Using a flow rate controller with different flow rate settings for different types of in-plane deformation could assist in dealing with different substrates. However, the use of a flow rate controller both increases complexity and cost.

A further problem is that it is difficult for a substrate holder to clamp warped substrates due to its limited supply of clamping fluid flow and the geometry of the warped substrate. With regard to the latter, in general flat and bowl shaped substrates tend to roll off a substrate holder from their centre outwards. Substrates with a mild umbrella shape also tend to roll off a substrate holder. This is due to most of the air escaping via an outside edge of the substrate when the substrate is pulled towards the substrate holder in a clamping operation. The pneumatic torque in this roll-off causes the substrate to bend downwards onto the burls. The pneumatic torque is caused by the pressure drop of the air flow just outside the most outward contact point of the substrate with the burls. After a short distance, that is typically a few millimetres, this pressure drop may quickly diminish at a curl-up.

The free height between a base surface of the substrate holder and the bottom surface of the substrate largely determines the pressure drop. U.S. Pat. No. 10,324,382 discloses varying the free height so as to vary the pressure drops. However, the free height is fixed and the non-adjustable differing local flow rates may, over time, introduce errors.

To address at least some of the disadvantages of known techniques, embodiments provide a substrate holder for supporting a substrate in which the free height between the base surface of the substrate holder and the bottom surface of the substrate is adjustable. This allows for local clamping fluid flow changes to be easily made as may be required for any of: handling of different substrates, handling substrates with specific deformations (in particular umbrella deformations), correcting specific local clamping flow issues (such as a leaky seal), or to perform compensations for previously incurred overlay inaccuracies (as may be required when a substrate is clamped to a substrate holder more than once during the forming of different and overlapping layers of a substrate).

In embodiments, the substrate holder is configured to support the substrate. The substrate holder may hold the substrate in place. The substrate holder may be positioned on, or may be part of the substrate support WT described above, i.e., the substrate holder and the substrate support WT may be made of a single piece. Further to this, the substrate holder may be configured to keep the substrate in place on the substrate holder in a particular position. This may otherwise be known as clamping the substrate.

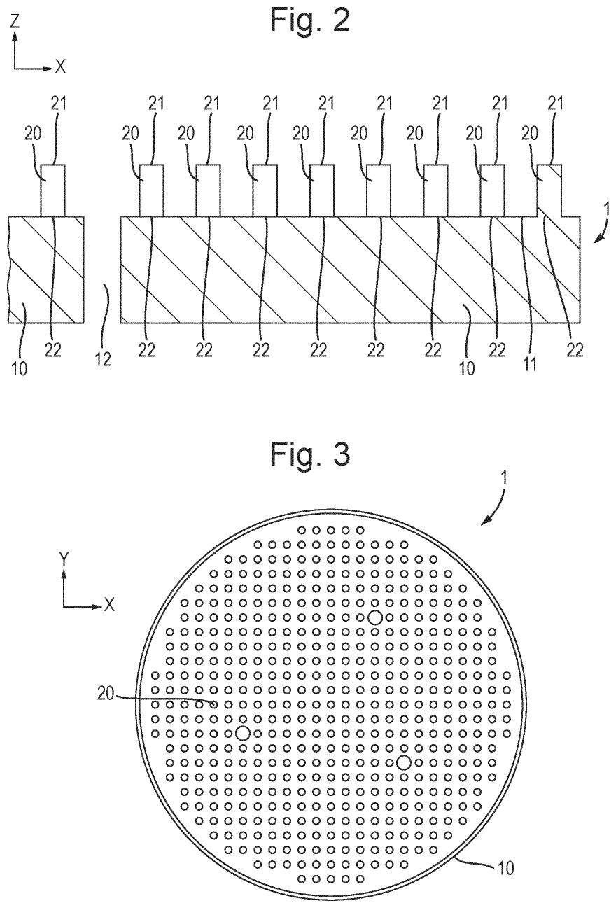

A partial cross section of a known substrate holder 1 is shown in FIG. 2. FIG. 3 depicts a plan view of the substrate holder of FIG. 2.

The substrate holder 1 comprises a main body 10 having a base surface 11. The main body 10 may form a substantial portion of the substrate holder 1. The base surface 11 may be a top surface of the main body 10 when positioned as shown in FIG. 2. Thus, the top surface may be an upper surface in the Z-direction as shown.

The substrate holder 1 comprises a plurality of burls 20 connected to the base surface 11 of the main body 10, as described above. The burls 20 may otherwise be referred to as supporting pins or projections. The plurality of burls 20 have proximal ends 22, which are situated near the main body 10 when in position, and distal ends 21. The distal ends 21 are at opposite ends of the plurality of burls 20 to the proximal ends 22, i.e. are situated at an end of the burl 20 away from the main body 10.

The distal ends 21 of the plurality of burls 20 form a support surface for a substrate W. The distal ends 21 of the plurality of burls 20 may be provided in a plane. Preferably, the support surface is formed in a substantially flat plane, i.e. the distal surfaces of the burls 20 may conform to a flat plane and support the substrate W. This is beneficial as the substrate W can be positioned on the support surface to also be substantially flat, which can reduce errors when patterning the substrate W.

The plurality of burls 20 may be connected to the base surface 11 of the main body 10 in any suitable way. The plurality of burls 20 may be separate components which are attached to the base surface 11 of the main body 10. Alternatively, the plurality of burls 20 may be integral to the main body 10. In other words, the plurality of burls 20 may be formed as protrusions from the base surface 11 of the main body 10, i.e. the plurality of burls 20 may be formed as a single part with the main body 10.

The substrate holder 1 may be configured to extract fluid from between the substrate W supported on the support surface and the base surface 11. As fluid is extracted, the pressure beneath the substrate W is reduced relative to pressure above the substrate W, and the edge of the substrate W will lower towards the substrate holder 1. The substrate W can be clamped by extracting fluid in the space below the substrate W to provide a reduced relative pressure in the space between the substrate holder 1 and the substrate W. The main body 10 may comprise at least one extraction port 12 through which the fluid is extracted. Although not shown in FIG. 2, the main body 10 may also comprise other types of ports and devices. In particular, the main body 10 may comprise elevation pins (not shown in figures) for assisting the removal of a substrate W from the substrate holder 1.

The pressure drop, and thereby clamping force, is dependent on the free height between the base surface 11, or what is effectively the base surface 11, and the surface of the substrate W that will contact the substrate holder 1, i.e. the bottom surface of the substrate W. Embodiments provide a technique for adjustably, and locally, varying the free height to thereby cause variations in the clamping force.

According to embodiments, removable structures are secured to the base surface 11 of the substrate holder 1. Each removable structure may effectively increase the height of the base surface 11 due to the upper surface of the removable structure providing an effective base surface of the substrate holder 1. The presence of each removable structure may effectively change the location of the proximal end 22 of at least some of the burls 20 from being at the base surface 11 to being at the upper surface of the removable structure. The heights of the burls 20 above the base surface 11 remain unchanged. However, the heights of the burls 20 above each effective base surface will be less than the heights of the burls 20 above the base surface 11. The free height may therefore be further defined between effective base surfaces, that result from the use of removable structures, and the bottom surface of the substrate W. The presence of removable structures causes a variation in the pressure drops, and thereby the clamping forces.

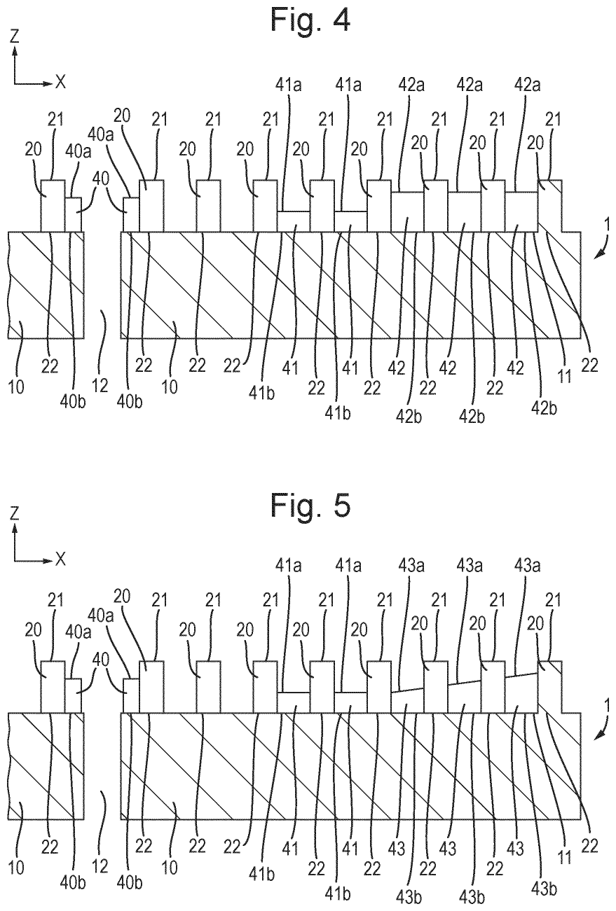

FIGS. 4 and 5 show removable structures 40, 41, 42, and 43 secured to the base surface 11 according to embodiments. The removable structures 40, 41, 42, and 43 may be used with the above-described known substrate holder 1, as shown in FIGS. 2 and 3.

Each structure 40, 41, 42, 43 may be secured to, and removed form, the base surface 11 of the substrate holder 1. Each structure 40, 41, 42, 43 is substantially planar. One of the major surfaces of each structure 40, 41, 42, 43 is a substrate holder facing surface 40b, 41b, 42b, 43b. Each substrate holder facing surface 40b, 41b, 42b, 43b is both securable to the base surface 11 of the substrate holder 1 and also removable from the base surface 11 of the substrate holder 1. The opposing major surface of each structure 40, 41, 42, 43 is a substrate facing surface 40a, 41a, 42a, 43a.

Each structure 40, 41, 42, 43 comprises plurality of apertures through the structure 40, 41, 42, 43 that are arranged such that burls 20 on the base surface 11 may pass through the respective apertures. The size and arrangement of the apertures may be dependent on the specific pattern of burls 20. The diameter of each aperture may be in the range 50 μm to 1000 μm, and is preferably in the range 210 μm to 350 μm. The pitch between adjacent apertures may be in the range 1 mm to 3 mm, and is preferably in the range 1.5 mm to 2.5 mm.

Each structure 40, 41, 42, 43 may further comprise one or more elevation pin receiving openings (not shown in figures) arranged such that one or more elevation pins on the base surface 11 may pass through respective elevation pin receiving openings.

Each structure 40, 41, 42, 43 may further comprise one or more extraction port openings arranged such that air flow through the extraction ports 12 of the substrate holder 1 are not obstructed.

Each structure 40, 41, 42, 43 may comprise an adhesive layer (not shown in the figures), on its substrate holder facing surface 40b, 41b, 42b, 43b that contacts the base surface 11, for adhering the structure 40, 41, 42, 43 to the base surface 11 of the substrate holder 1. The structure 40, 41, 42, 43 may thereby be a sticker. The structure 40, 41, 42, 43 may be removed from the substrate holder 1 by, for example, peeling the structure 40, 41, 42, 43 away from the substrate holder 1. All substantial traces of the adhesive may then be removed from the base surface 11. The adhesive may be chemically removed. If required, a new structure 40, 41, 42, 43 may then be adhered to the base surface 11. There may be a backing sticker (not shown in the figures) that covers the adhesive layer. The backing sticker is removed after the structure 40, 41, 42, 43 has been positioned on the base surface 11.

The adhesive may be pressure sensitive, as described by at least https://en.wikipedia.org/wiki/Pressure-sensitive_adhesive (as viewed on 22 Jun. 2021).

Characteristics of the pressure sensitive adhesive (PSA) may include visco-elastic behaviour—since this makes the PSA adapt to the surfaces on small scale, and thus enables sticking. Both the viscous and elastic behaviour are used in the sticking: after pressing it down on the substrate W, the adhesive flows to the correct shape to make the Vanderwaals forces act. Also the visco-elastic behaviour has a side advantage in that it prevents structure deformation by thermal expansion of the sticker. Characteristics of the pressure sensitive adhesive (PSA) may also include the majority of the internal crosslinking being done before the product is applied. This enables using a backing sheet that sticks to the outer surface of the PSA. The PSA may effectively stick to itself and this reduces the residue of adhesive that remains on a base surface 11 after a structure 40, 41, 42, 43 has been peeled off. Any PSA with low viscosity and tack to prevent residue after removal may be used in embodiments. For example, embodiments include the use of either ‘hot melt PSA’, or UV crosslink PSA that crosslinks by radiation, although the latter type of PSA is currently preferred. The typical peel resistance may be 0.5 to 2 N per 5 mm width at 200 mm/min peel speed at 90° C.

The adhesive may be any of RC26100, or other examples of hot melt such as Duro-Tak™ H112, HM796.

Alternatively, a permanent adhesive may be used. When a permanent adhesive is used, the adhesive may have a low glue strength, or be removable by a solvent, so that an adhered structure 40, 41, 42, 43 may be removed from the substrate holder 1.

Embodiments also include other techniques for securing each structure 40, 41, 42, 43 to the base surface 11. For example, electro-static clamping, a mechanical clip and/or bolts may be used. The structure 40, 41, 42, 43 may alternatively, or additionally, be held to the base surface 11 by an increased vacuum region at the structure 40, 41, 42, 43.

Each structure 40, 41, 42, 43 is preferably made from a thermoplastic material, polyether ether ketone, PEI and/or polyethylene. In particular, the materials may include Mylar, or general name BoPET (biaxially-oriented polyethylene terephthalate). Each structure 40, 41, 42, 43 may alternatively be made from metal.

The thickness of each structure 40, 41, 42, 43 may be defined as the distance between its substrate holder facing surface 40b, 41b, 42b, 43b and substrate facing surface 40a, 41a, 42a, 43a along a line that is normal to the substrate holder facing surface 40b, 41b, 42b, 43b. The thickness of each structure 40, 41, 42, 43 may be less than the height of each burl 20 above the base surface 11. Accordingly, the distal end 21 of each burl 20 may protrude out of the effective base surface provided by the substrate facing surface 40a, 41a, 42a, 43a of each structure 40, 41, 42, 43. The thickness of each structure 40, 41, 42, 43 may be less than 170 μm, and preferably 85 μm, 110 μm or 135 μm.

As shown by structure 43 in FIG. 5, one or more of the substrate facing surfaces 43a may be inclined relative to the substrate holder facing surface 43b that contacts the base surface 11. The incline of the substrate facing surfaces 43a may be linear, curved, or have any other profile.

Each substrate holder facing surface 40b, 41b, 42b, 43b and substrate facing surface 40a, 41a, 42a, 43a of a structure 40, 41, 42, 43 may be at least partially annular.

Each substrate holder facing surface 40b, 41b, 42b, 43b and substrate facing surface 40a, 41a, 42a, 43a of the structure 40, 41, 42, 43 may be at least partially circular.

The outer perimeter of each substrate holder facing surface 40b, 41b, 42b, 43b and substrate facing surface 40a, 41a, 42a, 43a of each structure 40, 41, 42, 43 may be less than the outer perimeter of the base surface 11 of the substrate holder 1.

Each substrate holder facing surface 40b, 41b, 42b, 43b and substrate facing surface 40a, 41a, 42a, 43a of the structure 40, 41, 42, 43 may be non-circular and non-annular.

As shown in FIGS. 4 and 5, embodiments include a plurality of different structures 40, 41, 42, 43 being secured to the same base surface 11. The plurality of structures 40, 41, 42, 43 may have different sizes and/or thicknesses. The thickness of each structure 40, 41, 42, 43 may be selected in dependence on the desired clamping force. The thickness of each structure 40, 41, 42, 43 may additionally, or alternatively, be selected in dependence on the heights of the burls 20. Although the burls 20 may preferably all have exactly the same height, manufacturing imperfections may result in slight variations between the actual burl heights. The thickness of each structure 40, 41, 42, 43 may be selected in dependence on the actual local burl heights. The structures 40, 41, 42, 43 may therefore allow any variation in the burl heights to, at least partially, be compensated for due to the clamping force variation caused by the structures 40, 41, 42, 43.

As explained earlier, the clamping forces applied to a substrate W are dependent on the free heights. At regions of the substrate holder 1 in which the structures 40, 41, 42, 43 are not present, the free height is defined as between the base surface 11 of the substrate holder and the bottom surface of the substrate W. At regions of the substrate holder 1 in which the structures 40, 41, 42, 43 are present, the free heights are defined as between the substrate facing surfaces 40a, 41a, 42a, 43a of the structures 40, 41, 42, 43 and the bottom surface of the substrate W. Advantageously, the structures 40, 41, 42, 43 allow local variations of the free height. The distance between the effective location of the proximal ends 22 of the burls 20 and the bottom surface of the substrate W, and/or the distal ends 21 of burls 20, may therefore be varied. Although the distance between the distal end 21 of each burl 20 and the base surface 11 remains constant, the free height may be changed due to the presence of a structure 40, 41, 42, 43. A plurality of structures 40, 41, 42, 43 with differing sizes, thicknesses and/or shapes may be used. In an embodiment, the distance between each substrate facing surface 40a, 41a, 42a, 43a of a structure 40, 41, 42, 43 and a distal end 21 of the burl 20 that protrudes through the structure 40, 41, 42, 43 may be between 10 μm and 200 μm, and is preferably 30 μm, 55 μm, 80 μm or 125 μm. The structures 40, 41, 42, 43 may be flexibly applied at any location on a base surface 11. For example, they may be applied around elevation pin receiving openings, tooling holes (not shown in figures), or any other potential leaky seal location (not shown in figures) where an increase of pressure drop is desired. The structures 40, 41, 42, 43 may be applied so that substrates W with umbrella shaped deformations may be appropriately clamped to. The structures 40, 41, 42, 43 may also be easily removed and/or replaced. Embodiments therefore allow adjustable control of pressure drops in substrate clamping operations.

In an embodiment, three annular structures may be concentrically secured to the base surface 11 of a substrate holder 1. The distance between the base surface 11 and the distal end 21 of each burl 20 may be about 170 μm. The substrate holder facing surface and substrate facing surface of a first one of the structures may have an inner radius of about 75 mm and an outer radius of about 100 mm. The first one of the structures may have a height of about 85 μm. The substrate holder facing surface and substrate facing surface of a second one of the structures may have an inner radius of about 100 mm and an outer radius of about 125 mm. The second one of the structures may have a height of about 110 μm. The substrate holder facing surface and substrate facing surface of a second one of a third one of the structures may have an inner radius of about 125 mm and an outer radius of about 145.1 mm. The third one of the structures may have and a height of about 135 μm. Tests found that the use of structures with such dimensions increased the clamping strength of the substrate holder 1 on a substrate W with a bowl deformation by a factor of about 1.7. On flat substrates W, the clamping force was still appropriate and the use of the structures did not change the substrate-to-substrate overlay accuracy.

Embodiments also include a method of making a structure 40, 41, 42, 43 for securing to a base surface 11. For example, laser ablation may be used to form the apertures or openings in the structures 40, 41, 42, 43, to generate any inclined substrate facing surfaces 40a, 41a, 42a, 43a of the structures 40, 41, 42, 43, and/or form to the structures 40, 41, 42, 43 into a particular shape.

Embodiments also include a method of adapting a substrate holder 1. The method comprises obtaining a substrate holder 1 that comprises a base surface 11 and securing one or more structures 40, 41, 42, 43 according to embodiments to the base surface 11. The method may further comprise further adapting the substrate holder 1 by removing one or more of the structures 40, 41, 42, 43 that were secured to the base surface 11.

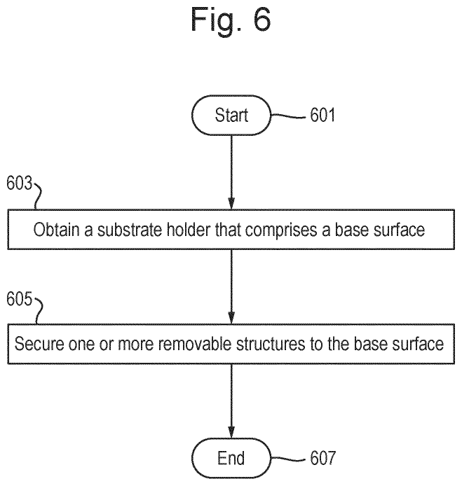

FIG. 6 shows a flowchart of a method according to an embodiment.

At step 601, the method begins.

At step 603, a substrate holder 1 is obtained.

At step 605, one or more removable structures are secured to a base surface 11 of the substrate holder 1.

At step 607, the method ends.

Embodiments also include the following numbered clauses:

1. A structure for use on a base surface of a substrate holder, wherein:
the structure is substantially planar with a substrate holder facing surface that is both securable to the base surface of the substrate holder and also removable from the base surface of the substrate holder; and
the structure comprises a plurality of apertures therethrough that are arranged such that a plurality burls on the base surface may pass through the respective apertures;
wherein:
the diameter of the apertures is in the range 50 μm to 1000 μm; and
the pitch between adjacent apertures is in the range 1 mm to 3 mm.
   2. The structure according to clause 1, further comprising an adhesive layer on the substrate holder facing surface for adhering the structure to the base surface of the substrate holder.
   3. The structure according to clause 2, wherein the adhesive comprises a pressure sensitive adhesive.
   4. The structure according to any preceding clause, wherein the structure comprises one or more of a thermoplastic material, polyether ether ketone, polyethylene and metal.
   5. The structure according to any preceding clause, further comprising one or more elevation pin receiving openings arranged such that one or more elevation pins on the base surface may pass through the respective elevation pin receiving openings; and/or
one or more extraction port openings arranged such that each air flow through an extraction port of the substrate holder is not obstructed.
   6. The structure according to any preceding clause, wherein:
the structure comprises a substrate facing surface that is an opposing major surface to the substrate holder facing surface; and
the substrate facing surface is inclined relative to the substrate holder facing surface.
   7. The structure according to any preceding clause, wherein the thickness of the structure is less than 170 μm, and is preferably 85 μm, 110 μm or 135 μm.
   8. The structure according to any preceding clause, wherein:
the structure comprises a substrate facing surface that is an opposing major surface to the substrate holder facing surface; and
the thickness of the structure is such that, when the structure is secured to a base surface of a substrate holder, the distance between the substrate facing surface and a distal end of a burl is between 10 μm and 200 μm, and is preferably 30 μm, 55 μm, 80 μm or 125 μm.
   9. The structure according to any preceding clause, wherein the substrate holder facing surface of the structure is at least partially annular.
   10. The structure according to any of clauses 1 to 8, wherein the substrate holder facing surface of the structure is at least partially circular.
   11. The structure according to any of clauses 1 to 8, wherein the substrate holder facing surface of the structure is non-circular and non-annular.
   12. The structure according to any preceding clause, wherein the outer perimeter of the substrate holder facing surface of the structure is less than the outer perimeter of the base surface of the substrate holder.
   13. A substrate holder configured to support a substrate, the substrate holder comprising:
a base surface;
a plurality of burls protruding from the base surface, wherein each burl has a distal end and the plurality of burls are arranged such that, when the substrate is supported by the substrate holder, the substrate is supported by the distal ends of the plurality of burls; and
at least one structure according to any preceding clause secured to the base surface.
   14. The substrate holder according to clause 13, the substrate holder comprising a plurality of structures according to any of clauses 1 to 12 secured to the base surface;
wherein the structures each have a different thickness.
   15. A substrate holder and one or more structures according to any of clause 1 to 12, wherein the substrate holder is configured to support a substrate, and the substrate holder comprises:
a base surface; and
a plurality of burls protruding from the base surface, wherein each burl has a distal end and the plurality of burls are arranged such that, when the substrate is supported by the substrate holder, the substrate is supported by the distal ends of the plurality of burls.
   16. The substrate holder and one or more structures according to clause 14, wherein there are a plurality of structures and the structures have different sizes, shapes and/or thicknesses.
   17. A lithographic apparatus comprising a substrate holder according to clause 13 or 14; and/or a substrate holder and one or more structures according to any of clauses 15 or 16.
   18. A method of adapting a substrate holder, the method comprising:
obtaining a substrate holder that comprises a base surface; and
securing one or more structures according to any of clauses 1 to 12 to the base surface;
wherein the substrate holder is configured to support a substrate and the substrate holder comprises a plurality of burls protruding from the base surface, wherein each burl has a distal end and the plurality of burls are arranged such that, when the substrate is supported by the substrate holder, the substrate is supported by the distal ends of the plurality of burls.
   19. The method according to clause 18, further comprising further adapting the substrate holder by removing one or more of the structures that were secured to the base surface.
   20. A substrate holder, comprising:
a base surface;
a plurality of burls that project from the base surface and are configured to support a substrate; and
a plurality of removable structures on the base surface;
wherein:
the plurality of removable structures each have a different thicknesses; and
the plurality of removable structures are each formed with a plurality of holes so as to accommodate a portion of the plurality of burls.
   21. A substrate holder, comprising:
a base surface;
a plurality of burls that project from the base surface and are configured to support a substrate; and
a plurality of removable structures on the base surface;
wherein:
the plurality of removable structures each have a different thicknesses; and
the plurality of removable structures each comprise an adhesive layer for adhering the structure to the base surface.
   22. A substrate holder, comprising:
a base surface;
a plurality of burls that project from the base surface and are configured to support a substrate; and
a plurality of removable structures on the base surface;
wherein:
the plurality of removable structures each have a different thicknesses; and
the plurality of removable members each comprise one or more of a thermoplastic material, polyether ether ketone, polyethylene and metal.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains one or multiple processed layers.

Although specific reference may have been made above to the use of embodiments of the invention in the context of optical lithography, it will be appreciated that the invention may be used in other applications.

While specific embodiments of the invention have been described above, it will be appreciated that the invention may be practiced otherwise than as described.

The descriptions above are intended to be illustrative, not limiting. Thus, it will be apparent to one skilled in the art that modifications may be made to the invention as described without departing from the scope of the claims set out below.

1. A structure for use on a base surface of a substrate holder, wherein the structure is substantially planar with a substrate holder facing surface that is both securable to the base surface of the substrate holder and also removable from the base surface of the substrate holder, the structure comprising a plurality of apertures therethrough that are arranged such that a plurality of burls on the base surface may pass through the respective apertures, wherein:
the diameter of the apertures is in the range 50 μm to 1000 μm; and
the pitch between adjacent apertures is in the range 1 mm to 3 mm.

2. The structure according to claim 1, further comprising an adhesive layer on the substrate holder facing surface for adhering the structure to the base surface of the substrate holder.

3. The structure according to claim 1, wherein the structure comprises one or more selected from: a thermoplastic material, polyether ether ketone, polyethylene or metal.

4. The structure according to claim 1, further comprising one or more elevation pin receiving openings arranged such that one or more elevation pins on the base surface may pass through the respective elevation pin receiving openings; and/or one or more extraction port openings arranged such that air flow through an extraction port of the substrate holder is not obstructed.

5. The structure according to claim 1, wherein:
the structure comprises a substrate facing surface that is an opposing major surface to the substrate holder facing surface and the substrate facing surface is inclined relative to the substrate holder facing surface; and/or
the structure comprises a substrate facing surface that is an opposing major surface to the substrate holder facing surface and the thickness of the structure is such that, when the structure is secured to a base surface of a substrate holder, the distance between the substrate facing surface and a distal end of a burl of the plurality of burls is between 10 μm and 200 μm.

6. The structure according to claim 1, wherein the thickness of the structure is less than 170 μm.

7. The structure according to claim 1, wherein the substrate holder facing surface of the structure is at least partially annular, at least partially circular, or non-circular and non-annular.

8. The structure according to claim 1, wherein the outer perimeter of the substrate holder facing surface of the structure is less than the outer perimeter of the base surface of the substrate holder.

9. A substrate holder configured to support a substrate, the substrate holder comprising:
a base surface;
a plurality of burls protruding from the base surface, wherein each burl has a distal end and the plurality of burls are arranged such that, when the substrate is supported by the substrate holder, the substrate is supported by the distal ends of the plurality of burls; and
at least one structure according to claim 1 secured to the base surface.

10. The substrate holder according to claim 9, wherein the at least one structure is a plurality of such structures secured to the base surface;
wherein the structures each have a different thickness.

11. A substrate holder and one or more structures according to claim 1, wherein the substrate holder is configured to support a substrate, and the substrate holder comprises:
a base surface; and
a plurality of burls protruding from the base surface, wherein each burl has a distal end and the plurality of burls are arranged such that, when the substrate is supported by the substrate holder, the substrate is supported by the distal ends of the plurality of burls.

12. The substrate holder and one or more structures according to claim 11, wherein the one or more structures is a plurality of such structures and the structures have different sizes, shapes and/or thicknesses.

13. A lithographic apparatus comprising the substrate holder and one or more structures according to claim 11.

14. A method of adapting a substrate holder, the method comprising:
obtaining a substrate holder that comprises a base surface; and
securing one or more structures according to claim 1 to the base surface,
wherein the substrate holder is configured to support a substrate and the substrate holder comprises a plurality of burls protruding from the base surface,
wherein each burl has a distal end, and
wherein the plurality of burls are arranged such that, when the substrate is supported by the substrate holder, the substrate is supported by the distal ends of the plurality of burls.

15. The method according to claim 14, further comprising further adapting the substrate holder by removing one or more of the one or more of the structures secured to the base surface.

16. A substrate holder system, comprising:
a base surface;
a plurality of burls that project from the base surface and are configured to support a substrate; and
a plurality of removable structures, wherein:
the plurality of removable structures each have a different thickness; and
the plurality of removable structures are each formed with a plurality of holes so as to accommodate a portion of the plurality of burls.

17. A substrate holder system, comprising:
a base surface;
a plurality of burls that project from the base surface and are configured to support a substrate; and
a plurality of removable structures on, or configured to be on, the base surface, wherein:
the plurality of removable structures each have a different thickness; and
the plurality of removable structures each comprise an adhesive layer to adhere the structure to the base surface and/or each comprise one or more selected from: a thermoplastic material, polyether ether ketone, polyethylene or metal.

18. The substrate holder system of claim 17, wherein the plurality of removable structures each comprise an adhesive layer to adhere the structure to the base surface.

19. The substrate holder system of claim 17, wherein the plurality of removable structures each comprise one or more selected from: a thermoplastic material, polyether ether ketone, polyethylene or metal.

20. The substrate holder system of claim 17, wherein the plurality of removable structures are each formed with a plurality of holes so as to accommodate a portion of the plurality of burls.
